(19) United States
(12) Patent Application Publication
(10) Pub. No.: US 2016/0013100 A1
(43) Pub. Date: Jan. 14, 2016

(54) VIA STRUCTURE AND METHOD OF FORMING THE SAME

(71) Applicant: UNITED MICROELECTRONICS CORP., Hsin-Chu City (TW)

(72) Inventors: Kun-Ju Li, Tainan City (TW); Po-Cheng Huang, Kaohsiung City (TW); Chih-Chien Liu, Taipei City (TW); Yu-Ting Li, Chiayi City (TW); Jen-Chieh Lin, Kaohsiung City (TW); Chang-Hung Kung, Kaohsiung City (TW); Wen-Chin Lin, Tainan City (TW); Chih-Hsun Lin, Ping-Tung County (TW); Kuo-Chin Hung, Changhua County (TW)

(21) Appl. No.: 14/461,433

(22) Filed: Aug. 17, 2014

(30) Foreign Application Priority Data
Jul. 14, 2014 (TW) 103124140

(51) Int. Cl. H01L 21/768; H01L 23/48

(52) U.S. Cl. CPC H01L 21/76871; H01L 21/76802; H01L 21/76843; H01L 23/481

(57) ABSTRACT

A via structure and a method of forming the same are provided. In the forming method of the present invention, a via is formed in a dielectric layer. Next, a U-shaped seed layer is formed in the via. After that, a conductive material is selectively formed in the via to form a conductive bulk layer in the via. Through the present invention, the purposes of effectively removing the overhang adjacent to the opening of the via and protecting the U-shaped seed layer in the via can be achieved.

### BACKGROUND OF THE INVENTION

1. Field of the Invention

The present invention relates to a via structure and a method of forming the same, and more particularly to a via structure including a U-shaped multilayer structure and a method of forming the same.

2. Description of the Prior Art

With the trend towards scaling down the critical dimension (CD) in semiconductor processes, conventional arts are miniaturizing the size of semiconductor devices, but have faced many problems in the integrated process: for example, improving the process of the wiring structure, especially when the CD is miniaturized to a certain degree.

In order for a miniaturized semiconductor device to achieve a highly integrated and high-speed operation, conventional arts utilize miniaturized through holes and inter-layer dielectric layers to form a multilayered interconnected wiring structure. The method of forming the wiring structure includes forming a through hole in a dielectric layer, then sequentially forming various films in the through hole. If, however, the CD is miniaturized to 28 nm, the current deposition technique is unable to provide preferable step coverage, which can easily result in defects, such as overhang. Overhangs may contact each other or cause films formed thereon to contact each other, such that other films cannot fill the through hole, resulting in a void. The entire electric performance of the semiconductor device will be seriously affected.

A planarization process, such as a chemical mechanic planarization (CMP) process, can be optionally performed in the art to remove the overhang, but this process will significantly reduce the height of the through hole, which will still affect the entire electric performance of the semiconductor device.

Therefore, the defects of the current deposition technique, such as overhang and void, cannot be resolved through current technology.

### SUMMARY OF THE INVENTION

It is one of the primary objectives of the present invention to provide a method to overcome the aforementioned overhang issues, which will form a device having improved electric property.

It is one of the primary objectives of the present invention to provide an improved via structure, which can provide preferable electric property.

To achieve the purpose described above, one embodiment of the present invention provides a method of forming the via structure. First, a via is formed in a dielectric layer. A U-shaped seed layer is formed in the via. A conductive material is then selectively formed in the via, so as to form a conductive bulk layer in the via.

To achieve the purpose described above, another embodiment of the present invention provides a via structure including at least one contact plug, disposed in a dielectric layer. The contact plug includes a conductive bulk layer and a U-shaped multilayer structure. The U-shaped multilayer structure surrounds the conductive bulk layer, and includes a seed layer and a barrier layer. The barrier layer is positioned between the dielectric layer and the seed layer.

The method of forming the via structure in the present invention mainly utilizes the overhang structure formed at the opening of the via as an etching mask, so as to protect the seed layer underlay while the overhang is removed. Thus, through the method of the present invention, a via structure including a U-shaped multilayer structure can be obtained, wherein the U-shaped multilayer structure includes a U-shaped seed layer and a U-shaped barrier layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 are schematic diagrams illustrating a method of forming a via structure according to a first embodiment of the present invention.

FIG. 6 to FIG. 7 are schematic diagrams illustrating a method of forming a via structure according to a second embodiment of the present invention.

FIG. 8 to FIG. 10 are schematic diagrams illustrating a method of forming a via structure according to a preferred embodiment of the present invention.

### DETAILED DESCRIPTION

In the following description, numerous specific details, as well as accompanying drawings, are given to provide a thorough understanding of the invention. It will, however, be apparent to one skilled in the art that the invention may be practiced without these specific details.

FIGS. 1 to 5 are schematic diagrams illustrating a method of forming a via structure according to a first embodiment of the present invention. As shown in FIG. 1, a dielectric layer 300 is provided, and at least one via 312 is formed from a top surface 310 of the dielectric layer 300 (for example, through a dry etching process), but this is not limited thereto. In other embodiments, the method of forming the via, as well as the practical example thereof, can be further modified according to requirements. The dielectric layer 300 is preferably formed on a substrate 100, such that a conductive region 110 of the substrate 100 can be exposed from the via 310 of the dielectric layer 300. Precisely speaking, at least a portion of the conductive region 110 is exposed from the via 312, but the present invention is not limited thereto. In addition, the substrate 110 may include a substrate made of semiconductor material, such as a silicon substrate, an epitaxial silicon substrate, a silicon germanium substrate, a silicon carbide substrate or a silicon-on-insulator (SOI) substrate, or a substrate made of non-semiconductor material, such as glass substrate. Otherwise, the substrate 100 can be a single layer or multilayered dielectric layers. In one embodiment, the conductive region can be made of material having a conductivity higher than that of the substrate: for example, the conductive region can be any doping region or a gate electrode while the dielectric layer is formed on a semiconductor substrate; or, the conductive region can be a portion of the metal interconnection system, such as a via plug or metal line, while the dielectric layer is formed on another dielectric layer.

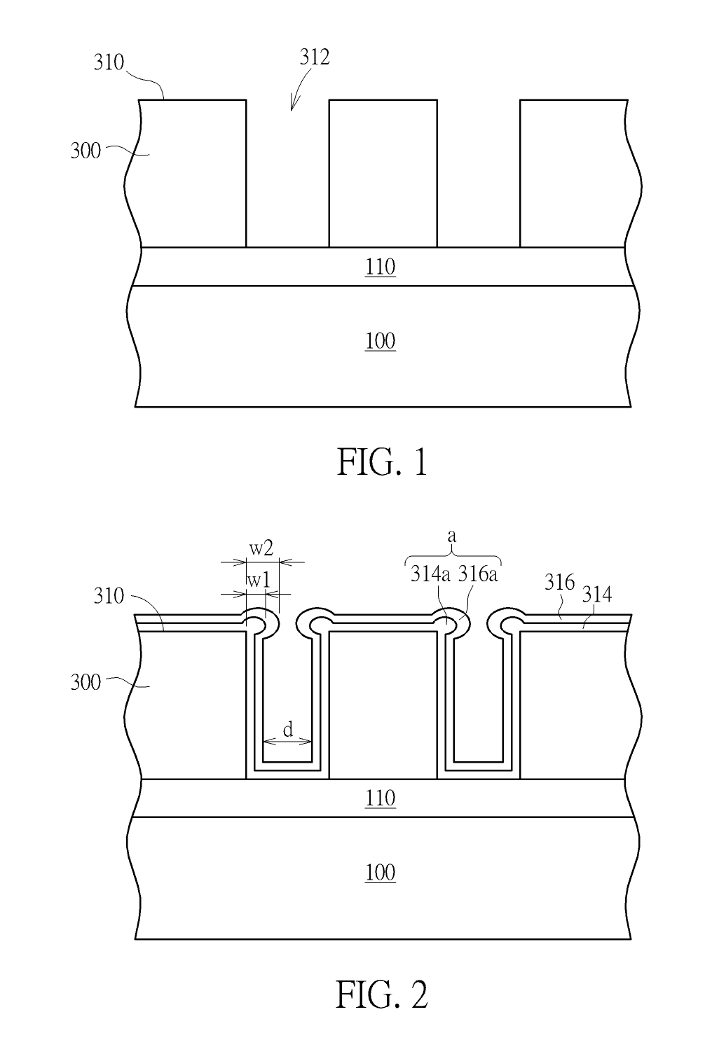

As shown in FIG. 2, a barrier material layer 314 and a seed material layer 316 are formed sequentially on the top surface 310 of the dielectric layer 300 and the surface of the via 312. The barrier material layer 314 and the seed material layer 316 entirely cover the top surface 310 of the dielectric layer 300, and the side wall and the bottom surface of the via 312, but do not fill the via 312. The method of forming the barrier material layer 314 and the seed material layer 316 can include a chemical vapor deposition (CVD) process or a physical vapor deposition (PVD) process, but is not limited thereto. It is noted that, due to the minimization of the semiconductor device, if the aspect ratio of the via is decreased, the barrier material layer 314 and/or the seed material layer 316 will easily form overhangs 314a, 316a, at the opening of the via 312, as shown in FIG. 2. In one embodiment, the width of the overhang is diverse according to the number of deposition layers, and the deposition temperature and the flow field. It should also be noted that the width of the overhang is defined as a distance between the outer side of the overhang and the opening of the via.

The overhangs 314a, 316a of the present embodiment are formed when the barrier material layer 314 and the seed layer 316 are deposited under a condition of 295° C. to 305° C. and 20 watts (W) to 200 watts. The barrier material layer 314 forms the overhang 314a adjacent to the opening of the via 312, the overhang 314a having a width w1; and the seed material layer 316 forms the overhang 316a adjacent to the opening of the via 312, the overhang 316a having a greater width w2 due to the overhang 314a. The width w2 is substantially ⅓ of a diameter d of the via 312, or greater than ⅓ of the diameter d of the via 312, but is not limited thereto. In one embodiment, the barrier material layer may include titanium (Ti), tantalum (Ta), titanium nitride (TiN), tantalum nitride (TaN) or a composition of the aforementioned materials; and the seed material layer may include tungsten (W) seed layer or cooper (Cu) seed layer, but is not limited thereto.

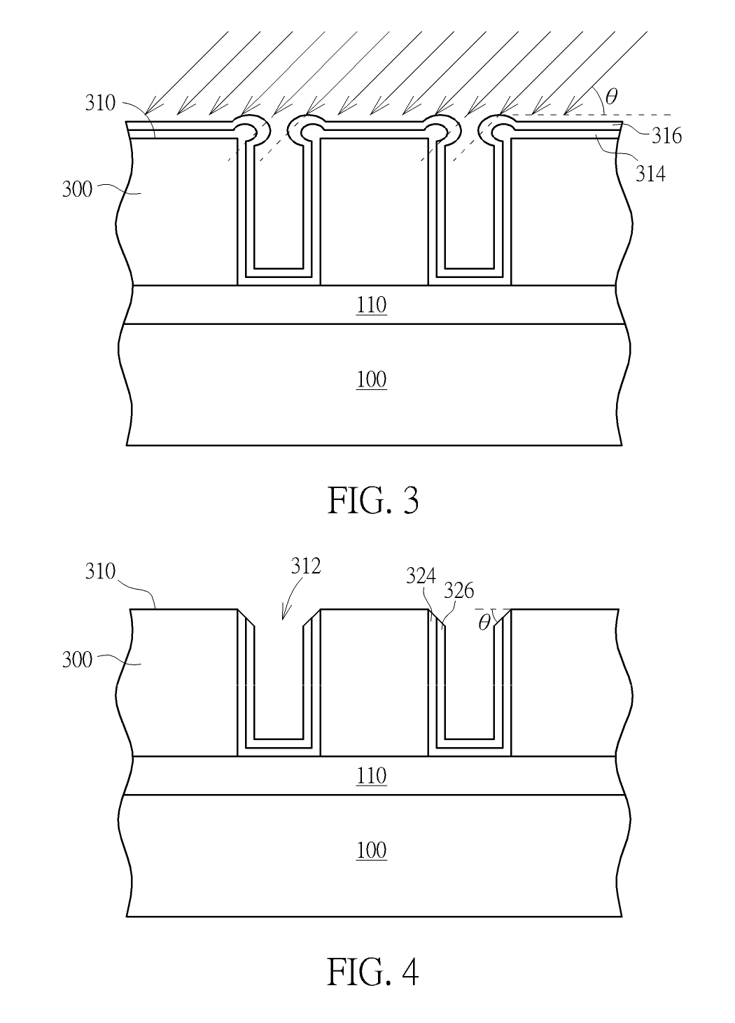

Next, as shown in FIG. 3 and FIG. 4, a removing process is performed to remove a portion of the barrier material layer 314 and a portion of the seed material layer 316 at the top surface 310 of the dielectric layer 300, and the overhang 316a. The removing process is performed through a dry etching process and may use a suitable etching gas, such as nitrogen trifluoride (NF₃). In the present embodiment, the removing process is preferably performed by using non-orthogonal plasma, wherein the non-orthogonal plasma has an angle θ to the top surface 310 of the dielectric layer 300, and the angle θ is between 10 degrees and 45 degrees. With such performance, the overhang 316a can be used as an etching mask to protect the seed material layer 316 in the via 312 and to prevent the seed material layer 316 below the overhang 316a from being etched during the removing process. Meanwhile, the non-orthogonal plasma can complete remove the overhang 316a, the portion of the barrier material layer 314 and the portion of the seed material layer 316 positioned on the top surface 310 of the dielectric layer 300, thereby forming a U-shaped seed layer 326 and a U-shaped barrier layer 324 in the via 312 with a U-shaped cross section, as shown in FIG. 4. Top surfaces 324a, 326a of the U-shaped seed layer 326 and the U-shaped barrier layer 324 are not level with the top surface 310 of the dielectric layer 300: one end of the top surfaces 324a, 326a is the same height as the top surface 310, and the other end of the top surfaces 324a, 326a is lower than the top surface 310 of the dielectric layer 300. Thus, the top surfaces 324a, 326a of the U-shaped seed layer 326 and the U-shaped barrier layer 324 forms an inclined plane. In one embodiment, there is an angle θ between the top surfaces 324a, 326a of the U-shaped seed layer 326 and the U-shaped barrier layer 324, and the top surface 310 of the dielectric layer 300, wherein the angle θ is between 10 degrees and 45 degrees.

In the aforementioned embodiment, although the method is illustrated by simultaneously removing the portion of the barrier material layer 314 and the portion of the seed material layer 316, the method of the present invention is not limited thereto. In another embodiment, the portion of the barrier material layer and the overhang thereof, and the portion of the seed material layer, and the overhangs thereof can also be optionally removed. In another embodiment, the angles of the non-orthogonal plasma for etching the barrier material layer and seed material layer can be the same or different, such that the angles between the top surface of the U-shaped seed layer and the top surface of the dielectric layer, and between the top surface of the U-shaped barrier layer and the top surface of the dielectric layer will be the same or different accordingly. The angles between the top surface of the U-shaped seed layer and the top surface of the dielectric layer, and between the top surface of the U-shaped barrier layer and the top surface of the dielectric layer are substantially between 10 degrees and 45 degrees, respectively.

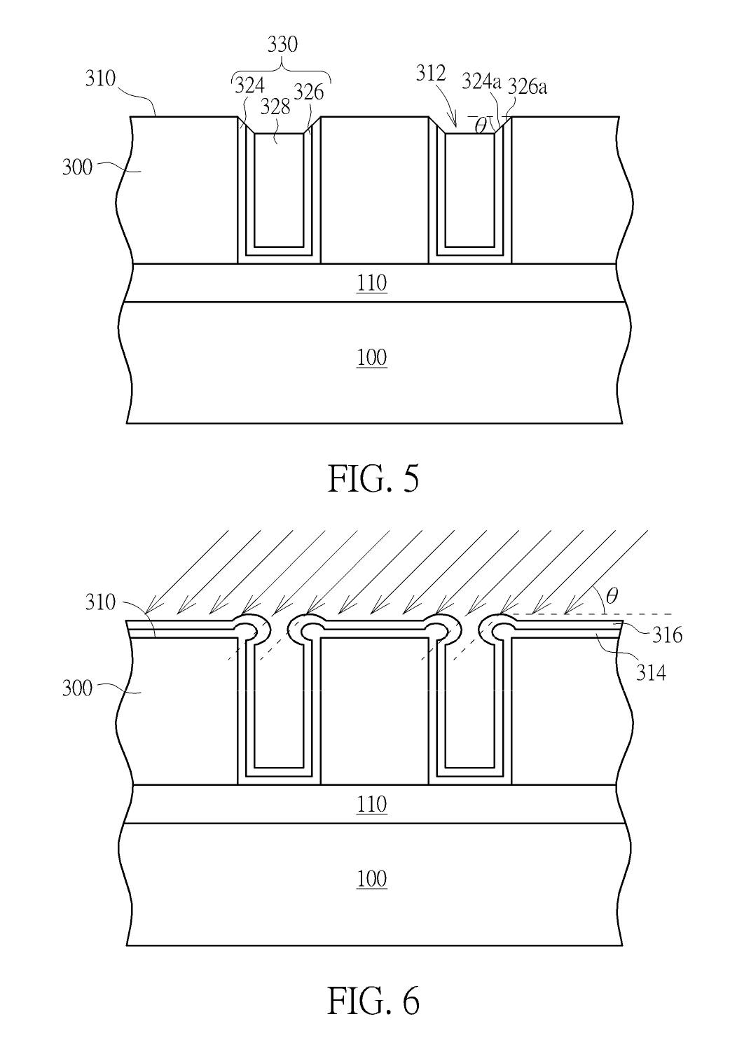

Next, as shown in FIG. 5, a conductive material is selectively formed on the U-shaped seed layer 326, wherein the conductive material includes the same material to the seed material layer, such as tungsten, cooper or aluminum, such that a conductive bulk layer 328 is formed in the via 312. The conductive bulk layer 328, the seed layer 326 and the barrier layer 324 compose a via plug 330, and the via plug 330 directly contacts the conductive region 110 of the substrate 100, with the via plug 330 being electrically connected to the conductive region 110 of the substrate 100.

The method of forming the conductive bulk layer 328 may include an electroplating process, or a non-electroplating process, but is not limited thereto. In other embodiments, the method of forming the conductive bulk layer can also be modified according to practical requirements. In a preferred embodiment of the present invention, the conductive bulk layer is preferably not higher than the opening of the via, and is slightly lower than the top surface of the dielectric layer, such that a planarization process is no longer needed. In another embodiment, a conductive bulk layer higher than the opening of the via can also be formed optionally, according to practical requirements. At this time, a planarization process such as a chemical mechanical polishing/planarization (CMP) or an etching process can be performed to remove the conductive bulk layer outside the via.

It is noted that the method of forming the via structure of the present invention mainly utilizes the defects (overhang) of current deposition techniques, with the overhang being used as an etching mask, to achieve the purpose of removing the overhang while keeping the seed layer in the via from being etched at the same time. Those with ordinary skill in the art will also know that the method of forming the via structure according to the present invention is not limited to the aforementioned steps, and can be achieved through other processes.

The following description will detail other embodiments of the method of forming the via structure according to the present invention. To simplify the description, the following description will detail the dissimilarities among those embodiments; identical features will not be described, and identical components in each of the following embodiments are marked with identical symbols.

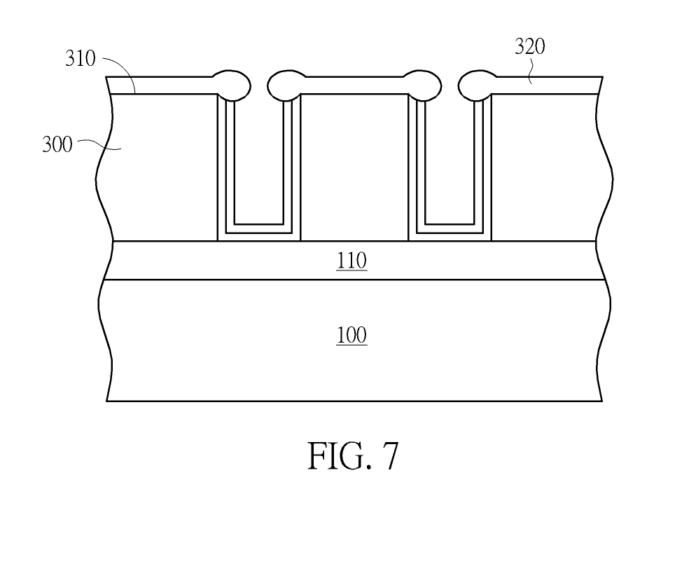

FIGS. 6 and 7 are schematic diagrams illustrating a method of forming a via structure according to a second embodiment of the present invention. It is noted that the method of the present embodiment and the aforementioned embodiment are different in that, after forming the structure shown in FIG. 2, an ion implantation process is performed to implant a specific dopant, such as arsenic (As), phosphorus (P), germanium (Ge) or indium (In) to the portion of the barrier material 314 and the portion of the seed material layer 316 on the top surface 310 of the dielectric layer 300, and the overhang 314a, 316a, wherein the specific dopant is highly selective relative to the undoped barrier material layer 314 and the seed material layer 316. With such an arrangement, a doped layer 320 that is highly etching-selective is formed at the portion of the barrier material 314 and the portion of the seed material layer 316 on the top surface 310 of the dielectric layer 300, and the overhang 314a, 316a, as shown in FIG. 7. The ion implantation process can be performed by optionally adjusting an implantation angle θ of the implanted dopant to a right angle or an inclined angle, for example. Preferably, the implanted dopant is implanted through an angle between 10 degrees and 45 degrees, but the present invention is not limited thereto. Also, the aforementioned ion implantation process is not limited to be performed only once, and can also include multiple processes in another embodiment.

Next, an etching process can be performed to remove the doped layer 320, and to form the U-shaped seed layer 326 and the U-shaped barrier layer 324 in the via 312, as shown in FIG. 4. After that, similar to the aforementioned embodiment, the conductive bulk layer 328 is selectively formed on the U-shaped seed layer 326, as shown in FIG. 5.

It is noted that the method of forming the via structure of the present invention can also utilize an ion implantation process to increase the etching selectivity of the overhang related to the seed layer in the via, to achieve the purpose of removing the overhang and protecting the seed layer more effectively. The method of forming the via structure can be applied to the manufacturing process of the semiconductor device, such as the conductive plug connected to the metal oxide semiconductor transistor.

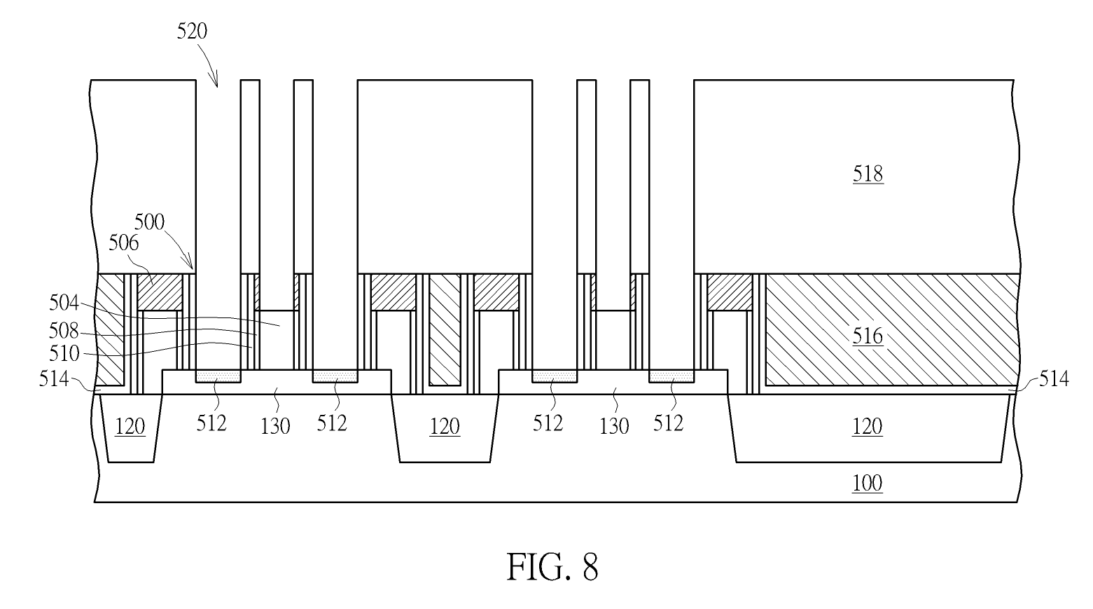

The following description will further illustrate a preferred example of the method of the present invention applied to a manufacturing process of the semiconductor device, with reference to FIGS. 8 to 10. As shown in FIG. 8, a MOS transistor 500 is formed in a substrate 100. The MOS transistor 500 can be a PMOS transistor or a NMOS transistor, and is preferably formed through a gate-last process, but is not limited thereto. The substrate 100 may be a silicon substrate, an epitaxial silicon substrate, a silicon germanium substrate, a silicon carbide substrate or a silicon-on-insulator (SOI) substrate. In addition, in one embodiment, a plurality of shallow trench isolations (STI) 120 can be formed in the substrate 100 for electrical isolation. Although the present embodiment is illustrated by using a Fin-FET transistor (the gate structure of the MOS transistor 500 of the present embodiment is formed on a fin structure 130 as shown in FIG. 8), in another embodiment, the method of forming the via structure of the present invention can also be applied to a planar transistor.

In one embodiment of the present invention, the MOS transistor 500 includes a gate dielectric layer 502, a gate 504, a cap layer 506, a liner layer 508, a spacer 510 and a source/drain region 512. The gate dielectric layer 502 may include silicon dioxide or silicon nitride; the gate 504 may include poly-silicon, which can be undoped poly-silicon, doped poly-silicon or amorphous silicon, or metal; the cap layer 506 includes silicon dioxide, silicon carbon, silicon nitride or silicon oxynitride; and the liner layer 508 includes silicon oxide. The spacer 510 can be a monolayer structure or a multilayer structure, which may include high temperature oxide (HTO), silicon nitride, silicon oxide, silicon oxynitride or HCD-SiN formed by hexachlorodisilane (Si₂Cl₆), for example.

A contact etch stop layer (CESL) 514, a first inter-layer dielectric (ILD) layer 516 and a second inter-layer dielectric (ILD) layer 518 are formed sequentially on the MOS transistor 500, wherein the material of the first inter-layer dielectric layer 516 and the second inter-layer dielectric layer 518 may be the same or different, and can be silicon nitride, silicon dioxide, silicon carbon, silicon carbonitride or silicon oxynitride, for example. As shown in FIG. 8, in one embodiment, a top surface of the first inter-layer dielectric layer 516 is vertically aligned with a top surface of the gate 504. Also, at least one trench 520 is formed in the first inter-layer dielectric layer 516 and the second inter-layer dielectric layer 518, corresponding to the gate 504 or the source/drain region 512 of the MOS transistor 500. In the present embodiment, the trench 520 penetrates the first inter-layer dielectric layer 516 and the second inter-layer dielectric layer 518, and at least a portion of the gate 504 and at least a portion of the source/drain region 512 can be exposed from the trench 520, but this is not limited thereto.

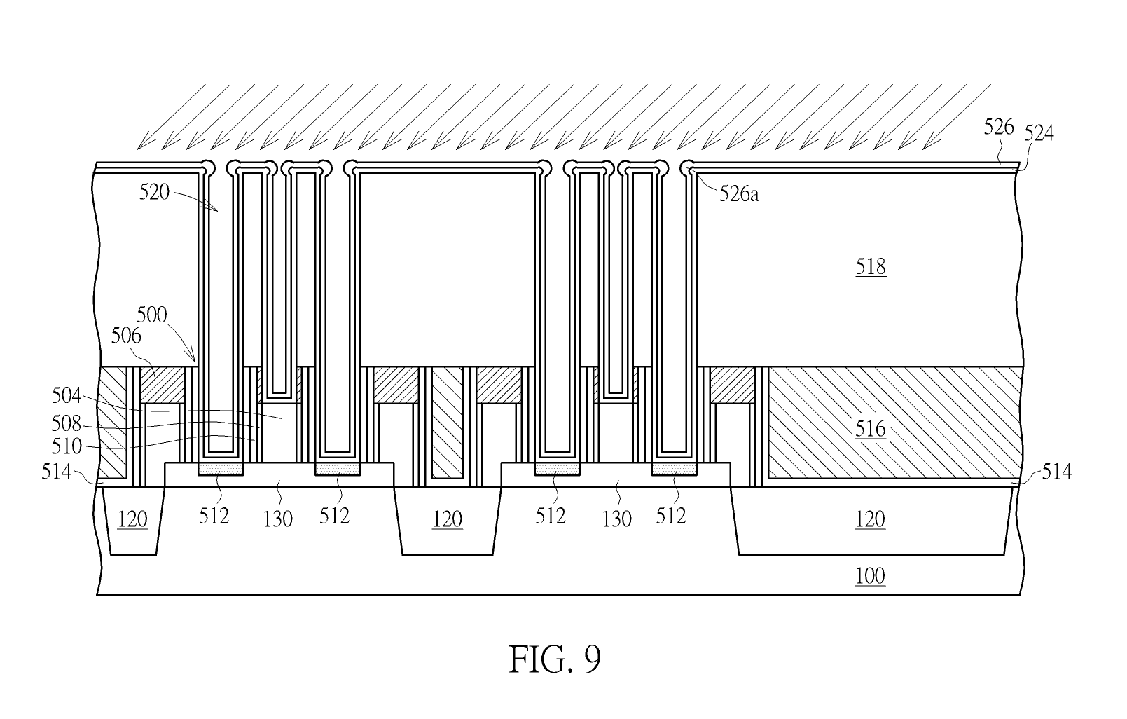

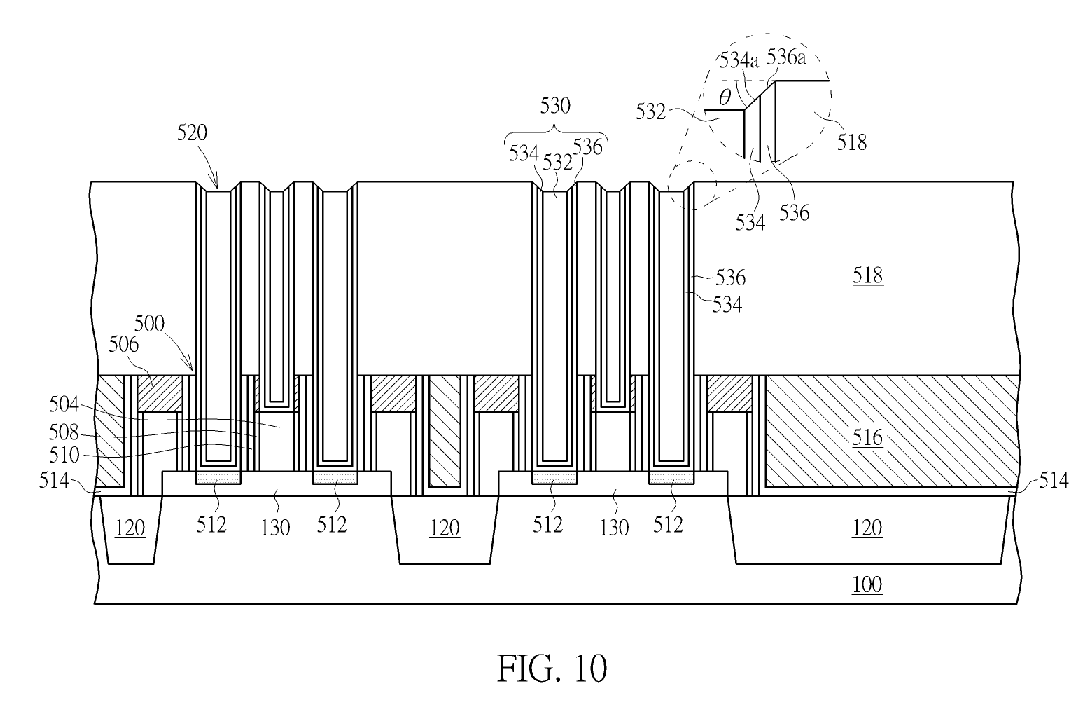

Next, as shown in FIGS. 9 and 10, a barrier material layer 524 and a seed material layer 526 are sequentially formed on the second inter-layer dielectric layer 518 entirely, with the barrier material layer 524 and the seed material layer 526 covering the surface of the second inter-layer dielectric layer 518, and the side wall and the bottom surface of the trench 520. The removing process according to the first embodiment of the present invention can then be optionally performed, by directly removing the portion of the barrier material layer 524 and the portion of the seed material layer 526 on the surface of the second inter-layer dielectric layer 518, and the overhang 526a. Alternatively, the removing process according to the second embodiment of the present invention can be performed, by firstly implanting the specific dopant to the portion of the barrier material layer 524 and the portion of the seed material layer 526 on the surface of the second inter-layer dielectric layer 518 and the overhang 526a, which increases the etching selectivity, and then removing the aforementioned portions.

A conductive material can be selectively formed in the trench 520, to form a via structure as shown in FIG. 10. The via structure includes a contact plug 530 disposed in the second inter-layer dielectric layer 518, wherein the contact plug 530 directly contacts the gate 504 or the source/drain region 512. The contact plug 530 includes a conductive bulk layer 532, and a seed layer 534 and barrier layer 536 surrounding the conductive bulk layer 532. The barrier layer 536 is disposed between the second inter-layer dielectric layer 518 and the seed layer 534. It should be noted that the seed layer 534 and the barrier layer 536 both have a U-shaped cross section, and the top surfaces of the seed layer 534 and the barrier layer 536 are not level with the top surface of the second inter-layer dielectric layer 518, but slightly lower than the top surface of the second inter-layer dielectric layer 518. Also, the top surfaces of the seed layer 534 and the barrier layer 536 form inclined planes 534a, 536a, with an angle between the inclined planes 534a, 536a, and the top surface of the second inter-layer dielectric layer 518 between 10 degrees and 45 degrees.

In summary, the method of forming the via structure of the present invention utilizes the defects (overhang) of current deposition techniques, by using the overhang as an etching mask, which achieves the purpose of protecting the seed layer in the via while removing the overhang. Through the method of the present invention, the via structure including the U-shaped seed layer and the U-shaped barrier layer can be obtained, which can provide preferable electric property. It is noted that the method of forming the via structure of the present invention can be applied in various manufacture processes, such as the contact plug or interconnection system manufacture processes. The present invention is not limited thereto, and the method of forming the via structure of the present invention can co-operate with any leading edge process in the art.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a via structure, comprising:
forming a via in a dielectric layer;
forming a U-shaped seed layer in the via only; and
selectively forming a conductive material in the via to form a conductive bulk layer in the via.

2. The method of forming a via structure according to claim 1, further comprising:
providing a substrate having a conductive region; and
forming the dielectric layer on the substrate, wherein at least a portion of the conductive region is exposed.

3. The method of forming a via structure according to claim 1, further comprising:
forming a seed material layer, wherein the seed material layer is at least disposed in the via; and
performing a removing process by removing a portion of the seed material layer to form the U-shaped seed layer.

4. The method of forming a via structure according to claim 1, further comprising:
forming a U-shaped barrier layer in the via, before forming the U-shaped seed layer.

5. The method of forming a via structure according to claim 3, further comprising:
before forming the seed material layer, forming a barrier material layer, the barrier material layer covering the via and a surface of the dielectric layer; and
performing a removing process by removing a portion of the barrier material layer to formed a U-shaped barrier layer.

6. The method of forming a via structure according to claim 3, wherein the removing process comprises a dry etching process.

7. The method of forming a via structure according to claim 3, wherein the removing process comprises:
performing an etching process by using non-orthogonal plasma, wherein the non-orthogonal plasma has an angle to the surface of the dielectric layer between 10 degrees and 45 degrees.

8. The method of forming a via structure according to claim 3, wherein the removing process comprises:
performing an ion implantation process on the portion of the seed material layer and removing the portion of the seed material layer.

9. The method of forming a via structure according to claim 5, wherein the removing process comprises:
performing an ion implantation process on the portion of the barrier material layer and removing the portion of the barrier material layer.

10. The method of forming a via structure according to claim 1, further comprising:
removing a portion of the conductive bulk layer outside the via.

11. The method of forming a via structure according to claim 3, wherein the seed material layer comprises an overhang at an opening of the via.

12. The method of forming a via structure according to claim 11, wherein the overhang has a width greater than ⅓ of a diameter of the via.

13. The method of forming a via structure according to claim 11, wherein the overhang is removed in the removing process to form the U-shaped seed layer.

14. A via structure, comprising:
at least one contact plug disposed in a dielectric layer, the contact plug comprising:
a conductive bulk layer; and
a U-shaped multilayer structure surrounding the conductive bulk layer, wherein the U-shaped multilayer structure comprises a seed layer and a barrier layer and the barrier layer is positioned between the dielectric layer and the seed layer.

15. The via structure according to claim 14, wherein the dielectric layer comprises at least one via, and the contact plug is positioned in the via.

16. The via structure according to claim 14, wherein the seed layer comprises a top surface, and the top surface is not level with a surface of the dielectric layer.

17. The via structure according to claim 16, wherein the top surface of the seed layer is substantially lower than the surface of the dielectric layer.

18. The via structure according to claim 16, wherein there is an angle between the top surface of the seed layer and the surface of the dielectric layer between 10 degrees and 45 degrees.

19. The via structure according to claim 14, wherein the barrier layer comprises a top surface, the top surface of the barrier layer is substantially lower than a surface of the dielectric layer, and there is an angle between the top surface of the barrier layer and the surface of the dielectric layer between 10 degrees and 45 degrees.

20. The via structure according to claim 14, further comprising a substrate, the substrate comprising a conductive region, wherein the dielectric layer is positioned on the substrate and the contact plug directly contacts the conductive region of the substrate.
